(19) United States
(12) Patent Application Publication
(10) Pub. No.: US 2020/0212227 A1
(43) Pub. Date: Jul. 2, 2020

(54) THIN FILM TRANSISTOR, MANUFACTURING METHOD THEREOF, ARRAY SUBSTRATE, DISPLAY DEVICE

(71) Applicant: BOE TECHNOLOGY GROUP CO., LTD., Beijing (CN)

(72) Inventors: Dong LI, Beijing (CN); Yucheng CHAN, Beijing (CN); Shuai ZHANG, Beijing (CN)

(21) Appl. No.: 15/751,220

(22) PCT Filed: Aug. 9, 2016
(86) PCT No.: PCT/CN2017/096590

§ 371 Date: Feb. 8, 2018

(30) Foreign Application Priority Data
Aug. 17, 2016 (CN) 201610683465.0

(51) Int. Cl. H01L 29/786; H01L 27/12; H01L 29/66; H01L 21/265

(52) U.S. Cl. CPC H01L 29/78696; H01L 27/1214; H01L 21/26513; H01L 29/78666; H01L 29/66757; H01L 29/78675

(57) ABSTRACT

A thin film transistor, a manufacturing method thereof, an array substrate and a display device are disclosed. The thin film transistor includes an active layer, as well as a source and a drain above the active layer, wherein the active layer includes a carrier trapping portion configured to trap photo-generated majority carriers.

### RELATED APPLICATION

The present application is the U.S. national phase entry of PCT/CN2017/096590, with an international filing date of Aug. 9, 2017, which claims the benefit of Chinese Patent Application No. 201610683465.0, filed on Aug. 17, 2016, the entire disclosure of which is incorporated herein by reference.

### FIELD

The present disclosure relates to the field of display technologies, and particularly to a thin film transistor, a manufacturing method thereof, an array substrate, and a display device.

### BACKGROUND

Thin Film Transistors (TFTs) are widely used in products with display function such as computers, mobile phones, and the like. Typically, a photo-induced leakage current would be generated when an active layer of a TFT is irradiated by light. Specifically, when the energy of a photon in the light irradiating the active layer is higher than 1.12 eV (i.e. the forbidden band width of silicon element that forms the active layer), electron-hole pairs may be generated in the active layer by excitation, such that the active layer is in a non-equilibrium state. In this case, part of the above electron-hole pairs are separated under the effect of an electric field, so that holes flow to a channel of the TFT while electrons flow to a drain thereof, thereby forming a leakage current. Such a photo-induced leakage current degrades the performance of the TFT.

### SUMMARY

Embodiments of the present disclosure provide an improved thin film transistor, a manufacturing method thereof, an array substrate, and a display device.

An aspect of the present disclosure provides a thin film transistor comprising an active layer, as well as a source and a drain above the active layer, wherein the active layer comprises a carrier trapping portion configured to trap photo-generated majority carriers.

According to some embodiments, the carrier trapping portion is between orthographic projections of the source and the drain on the active layer.

According to some embodiments, the carrier trapping portion is at a side of the active layer which is closer to the drain than the source.

According to some embodiments, the thin film transistor further comprises a gate, wherein the carrier trapping portion comprises a first sub-trapping portion and a second sub-trapping portion, the first is sub-trapping portion is between orthographic projections of the gate and the drain on the active layer, and the second sub-trapping portion is between orthographic projections of the gate and the source on the active layer.

According to some embodiments, the thin film transistor is a top gate type thin film transistor.

According to some embodiments, the first sub-trapping portion and the second sub-trapping portion have a size of about 0.3 μm to 2 μm in a length direction of a channel of the thin film transistor.

Another aspect of the present disclosure provides a manufacturing method of a thin film transistor, comprising forming an active layer; selectively processing a portion of the active layer to form a carrier trapping portion, wherein the carrier trapping portion is configured to trap photo-generated majority carriers; forming a source and a drain.

According to some embodiments, the selectively processing a portion of the active layer to form a carrier trapping portion comprises performing a selective ion bombardment process on the portion of the active layer.

According to some embodiments, the selectively processing a portion of the active layer to form a carrier trapping portion comprises performing a selective ion doping process on the portion of the active layer.

According to some embodiments, in the case where the carrier trapping portion is configured to trap photo-generated electrons, the selective ion doping process comprises performing selective doping on the portion of the active layer using gold ions or copper ions.

According to some embodiments, the ion bombardment process comprises performing selective bombardment on the portion of the active layer using ions of about 500 eV to 5 keV for about 50 s to 200 s.

According to some embodiments, the ions comprise inert elements such as argon (Ar), neon (Ne), helium (He), and the like.

A further aspect of the present disclosure provides an array substrate comprising a substrate, and any of the above-described thin film transistors on the substrate.

Yet another aspect of the present disclosure provides a display device comprising the array substrate described above.

Embodiments of the present disclosure provide an improved thin film transistor, a manufacturing method thereof, an array substrate and a display device. The thin film transistor comprises an active layer above a substrate, as well as a source and a drain above the active layer, wherein the active layer comprises a carrier trapping portion configured to trap photo-generated majority carriers. In this case, when the semiconductor active layer generates electron-hole pairs under light irradiation and the electron-hole pairs are separated under the effect of an electric field, on the one hand, the carrier trapping portion will trap the photo-generated majority carriers (which are electrons in the example of an n-type semiconductor active layer) in a free state, and the trapped photo-generated majority carriers will be recombined with corresponding minority carriers (which are holes in the example of an n-type semiconductor active layer) via the recombination center in the semiconductor active layer so as to reduce the time for the majority carriers being in a free state, so that the number of the photo-generated carriers inside the semiconductor active layer is somewhat reduced after the semiconductor active layer reaches a stable state, finally achieving the purpose of reducing the photo-induced leakage current.

### BRIEF DESCRIPTION OF DRAWINGS

To illustrate the technical solutions in the embodiments of the present disclosure more clearly, the accompanying drawings required for describing the embodiments will be introduced below briefly. Apparently, the accompanying drawings in the description below show merely some embodiments of the present disclosure. Those ordinarily skilled in the art may also derive other drawings from these accompanying drawings without spending inventive efforts.

FIG. 1 is a schematic structural diagram of a bottom gate type TFT provided by an embodiment of the present disclosure;

FIG. 2 is a schematic structural diagram of a top gate type TFT provided by an embodiment of the present disclosure;

FIG. 3 is a schematic structural diagram of another top gate type TFT provided by an embodiment of the present disclosure;

FIG. 4 is a flow chart illustrating a manufacturing method of a TFT as provided by an embodiment of the present disclosure;

FIG. 5 is a flow chart illustrating a specific implementation of step S102 in FIG. 4;

FIG. 6 is a schematic diagram showing a fabrication process of step S201 in FIG. 5;

FIG. 7 is a schematic diagram showing a part of the fabrication process of step S202 in FIG. 5;

FIG. 8 is a schematic diagram showing a part of the fabrication process of step S202 in FIG. 5;

FIG. 9 is a schematic diagram showing the fabrication process of step S203 in FIG. 5;

FIG. 10 is a flow chart illustrating another specific implementation of step S102 in FIG. 4.

FIG. 11 is a schematic diagram showing an ion doping process provided by an embodiment of the present disclosure.

### DETAILED DESCRIPTION

Technical solutions in embodiments of the present disclosure will be described below in a clear and complete manner with reference to the to accompanying drawings therein. Apparently, the described embodiments are merely a part but not all of the embodiments of the present disclosure. All other embodiments obtained by persons of those ordinarily skilled in the art based on the embodiments of the present disclosure without spending inventive efforts shall fall within the protection scope of the is present disclosure.

In the drawings, the following reference numerals are used:

01 - substrate; 10 - source; 11 - drain; 12 - semiconductor active layer; 120 - carrier trapping portion; 1201 - first sub-trapping portion; 1202 - second sub-trapping portion; 13 - gate; 14 - gate insulating layer; 20 - photoresist; 30 - mask; 40 - ion; A - position where a carrier trapping portion is to be formed; M - interstitial impurity; N - substitutional impurity.

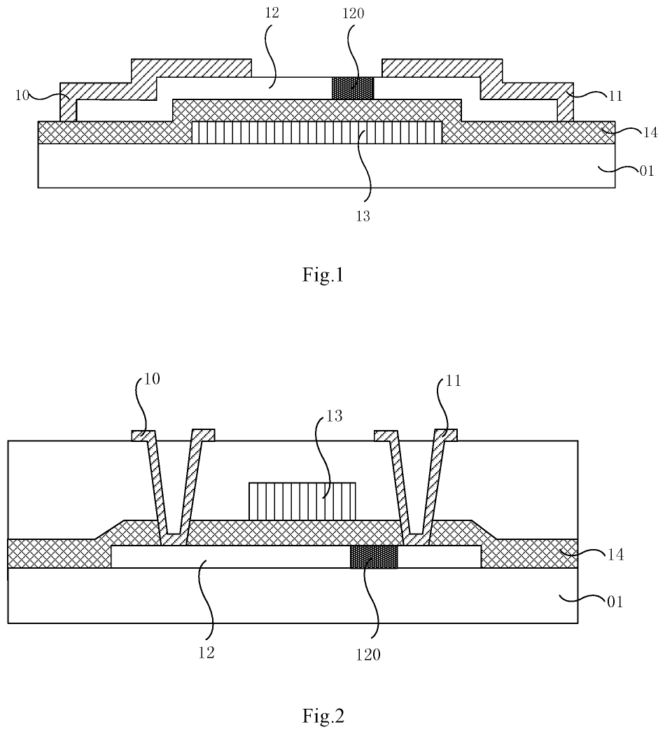

Embodiments of the present disclosure provide a TFT comprising, as shown in FIG. 1 or FIG. 2, an active layer 12 above a substrate 01, as well as a source 10 and a drain 11 above the active layer 12. The active layer 12 comprises a carrier trapping portion 120 between orthographic projections of the source 10 and the drain 11 on the active layer 12 (hereinafter, simply referred to as the carrier trapping portion 120 being between the source 10 and the drain 11), and configured to trap photo-generated majority carriers.

It is to be noted that the type of the TFT is not limited in the present disclosure, which may be a bottom gate type TFT as shown in FIG. 1 or a top gate type TFT as shown in FIG. 2. The bottom gate type TFT and the top gate type TFT are divided according to the upper and lower positions of a gate 13 and a gate insulating layer 14 with respect to the substrate 01. Specifically, for a bottom gate type TFT, as shown in FIG. 1, the gate 13 is closer to the substrate 01 than the gate insulating layer 14, and for a top gate type TFT, as shown in FIG. 2, the gate insulating layer 14 is closer to the substrate 01 than the gate 13.

The carrier trapping portion 120 comprises photo-generated majority carrier traps, i.e. impurities or deficiencies capable of trapping the photo-generated majority carriers in the active layer 12. Specifically, if the active layer 12 comprises an n-type semiconductor material, the carrier trapping portion 120 comprises photo-generated electron traps; if the active layer 12 comprises a p-type semiconductor material, the carrier trapping portion 120 comprises photo-generated hole traps. In practice, ion is bombardment may be performed at the position in the active layer 12 where the carrier trapping portion 120 is to be formed using an ion bombardment process so as to break covalent bonds between semiconductor elements, thereby forming the above deficiencies. Alternatively, atoms of an element different from the semiconductor material that forms the active layer 12 are doped as impurity atoms into the semiconductor material using an ion doping process to replace the original lattice atoms or to be embedded into interstices between the original lattice atoms.

In this case, when the active layer 12 generates electron-hole pairs under light irradiation and the electron-hole pairs are separated under the effect of an electric field, on the one hand, the carrier trapping portion will trap the photo-generated majority carriers (which are electrons in the example of an n-type semiconductor active layer) in a free state, and the trapped photo-generated majority carriers will be recombined with corresponding minority carriers (which are holes in the example of an n-type semiconductor active layer) via the recombination center in the semiconductor active layer so as to reduce the time for the majority carriers being in a free state, so that the number of the photo-generated carriers inside the active layer 12 is somewhat reduced after the active layer 12 reaches a stable state, finally achieving the purpose of reducing the photo-induced leakage current. In the meantime, in the embodiments of the present disclosure, the size and shape of the TFT's gate are not adjusted during the process of reducing the photo-induced leakage current, thus it is possible to avoid a decrease in the pixel aperture ratio caused by shielding the active layer from light by changing the size and shape of the gate.

Taking the n-type semiconductor active layer 12 as an example, the majority carriers are electrons. Under light irradiation, most of the photo-generated electrons will be trapped by the photo-generated electron traps in the carrier trapping portion. Therefore, from the beginning of light irradiation to reaching a stable state, the process of gradually filling the is photo-generated electron traps is further comprised. When the light irradiation stops, besides that non-equilibrium electrons in the conduction band are recombined with holes via recombination centers in the n-type semiconductor active layer, electrons in the photo-generated electron traps are also gradually released and recombined with holes via the recombination centers, so that an equilibrium state can be achieved.

For the n-type semiconductor active layer described above, almost all of the photo-generated holes are considered to be at the recombination centers, while the photo-generated electrons are substantially trapped by the carrier trapping portion completely. In this way, recombination probability of the photo-generated electrons in the conduction band is increased, thereby achieving the purpose of reducing the photo-induced leakage current.

The case of a p-type semiconductor active layer is similar to that of the n-type semiconductor active layer, except that the majority carriers are holes.

It is to be noted that, in the present disclosure, the area of the carrier trapping portion 120 between the source 10 and the drain 11 is not limited. For example, it may be the case that the entire active layer 12 between the source 10 and the drain 11 is the above-described carrier trapping portion 120. In this case, the carrier trapping portion 120 has the strongest ability to trap carriers, and the photo-induced leakage current of the TFT is smallest. On the other hand, however, since the carrier trapping portion 120 substantially occupies a channel position, the electron mobility of the TFT would be greatly decreased, thereby affecting the turn-on performance of the TFT. Therefore, in order to ensure the electron mobility of the TFT to during the course of trapping the photo-generated majority carriers by the above-described carrier trapping portion 120, optionally, a portion of the active layer 12 between the source 10 and the drain 11 may be used as the carrier trapping portion 120 described above.

In this case, since the electric field intensity at edges of the TFT is channel is large and the electric field at the edge of the channel close to the drain 11 is larger, the electron-hole pairs are most easily separated there, thereby generating a leakage current. Therefore, optionally, as shown in FIG. 1 or FIG. 2, the above-described carrier trapping portion 120 may be located at a side close to the drain 11 so as to trap the photo-generated majority carriers separated at the position close to the drain 11 to reduce the time for the photo-generated majority carriers being in a free state.

In addition, the semiconductor material constituting the active layer 12 is not limited in the present disclosure. For example, amorphous silicon or polycrystalline silicon may be used. Optionally, use of the low temperature poly-silicon (LTPS) technology with a process temperature lower than 600° C. can make the electron mobility of the TFT higher, which may be, for example, up to 300 cm²/V·s. On such basis, for a LTPS TFT, the top gate type structure has superior performance with respect to the bottom gate type structure for the parasitic capacitance in the top gate type LTPS TFT can be reduced by a self-alignment process of the gate 13.

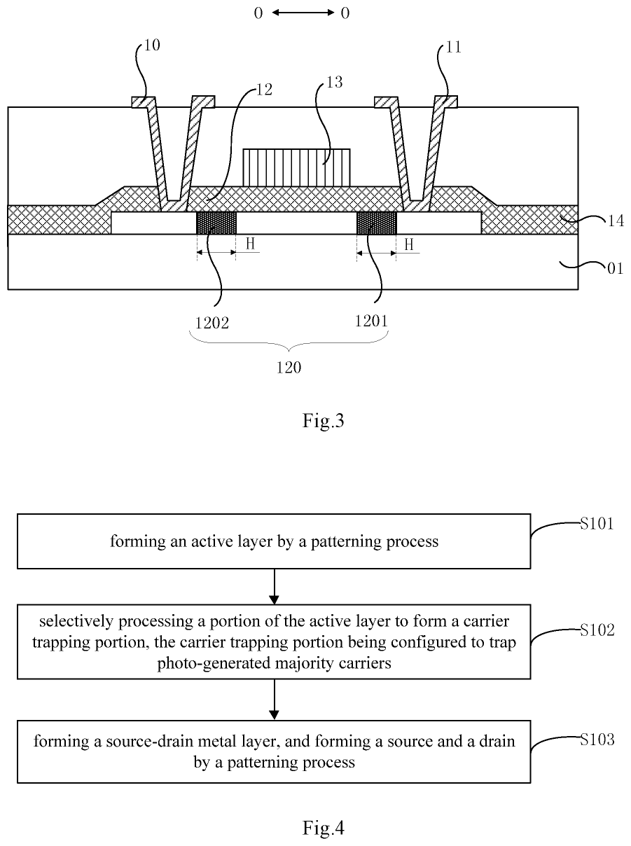

According to an exemplary embodiment, when the TFT has a top gate type structure, as shown in FIG. 3, the carrier trapping portion 120 comprises a first sub-trapping portion 1201 and a second sub-trapping portion 1202.

The first sub-trapping portion 1201 is between orthographic projections of the gate 13 and the drain 11 on the active layer 12, and the second sub-trapping portion 1202 is between orthographic projections of the gate 13 and the source 10 on the active layer 12. As a result, due to a larger electric field intensity at edges of the TFT channel, the electron-hole pairs are most easily separated there, thereby generating a leakage current. to Therefore, the photo-generated majority carriers separated at a position close to the drain 11 can be trapped by the first sub-trapping portion 1201 between the gate 13 and the drain 11, and the the photo-generated majority carriers separated at a position close to the source 10 can be trapped by the second sub-trapping portion 1202 between the gate 13 and the source 10, is thereby achieving the purpose of reducing the time for the photo-generated majority carriers being in a free state.

On such basis, optionally, as shown in FIG. 3, the first sub-trapping portion 1201 and the second sub-trapping portion 1202 have a size H of about 0.3 μm to 2 μm along a length direction of a channel O-O of the TFT. On the one hand, when the size H of the first sub-trapping portion 1201 and the second sub-trapping portion 1202 is less than about 0.3 μm, the precision of the manufacturing process would be increased, which is not conducive to reducing the production cost. Moreover, if the above size H is too small, the ability of the carrier trapping portion 120 to trap the photo-generated majority carriers would be decreased, which is disadvantageous to reducing the photo-induced leakage current. On the other hand, when the size H of the first sub-trapping portion 1201 and the second sub-trapping portion 1202 is greater than about 2 μm, although the ability of the carrier trapping portion 120 to trap photo-generated majority carriers can be enhanced, the electron mobility of the TFT would be decreased, thereby degrading the turn-on performance of the TFT. Therefore, when the size H of the first sub-trapping portion 1201 and the second sub-trapping portion 1202 is about 0.3 μm to 2 μm, not only the electron mobility of the TFT can be ensured, but also the photo-induced leakage current can be reduced. On such basis, the above size H may be 0.5 μm, 0.8 μm, 1.2 μm, and 1.8 μm.

Embodiments of the present disclosure provide an array substrate which comprises a substrate and any of the above-described TFTs on the substrate, and thus has the same structure and beneficial advantages as the TFTs provided by the foregoing embodiments. Since the structure and beneficial effects of the TFT have been described in detail in the foregoing embodiments, details are not described here again.

Embodiments of the present disclosure provide a display device which comprises the array substrate described above, and thus has the same beneficial effects as the foregoing embodiments. Details are not described here again.

Embodiments of the present disclosure provide a manufacturing method of a TFT comprising, as shown in FIG. 4, in step S101, forming an active layer by a patterning process.

In the present disclosure, the patterning process may refer to a process which comprises a photolithography process or a photolithography process as well as an etching step, and may further comprise other processes for forming a predetermined pattern, such as printing, inkjet, and the like. The photolithography process refers to a process that comprises film formation, exposure, development and other processes and forms a pattern using a photoresist, a mask, an exposure machine, and so on. A corresponding patterning process may be selected according to the structure formed in the present disclosure.

In step S102, a portion of the active layer 12 is selectively processed to form a carrier trapping portion. The carrier trapping portion is configured to trap photo-generated majority carriers.

In step S103, a source-drain metal layer is formed, and a source and a drain are formed by a patterning process.

In this case, when the active layer generates electron-hole pairs under light irradiation and the electron-hole pairs are separated under the effect of an electric field, on the one hand, the carrier trapping portion will trap the photo-generated majority carriers (which are electrons in the example of an n-type semiconductor active layer) in a free state, and the trapped photo-generated majority carriers will be recombined with corresponding minority carriers (which are holes in the example of an n-type semiconductor active layer) via recombination centers in the semiconductor active layer so as to reduce the time for the electrons or holes being in a free state in the conduction band, so that the number of the photo-generated carriers inside the active layer is somewhat reduced after the active layer reaches a stable state, finally achieving the purpose of reducing the photo-induced leakage current. In the meantime, in the embodiments of the present disclosure, the size and shape of the TFT's gate are not adjusted during the process of reducing the photo-induced leakage current, thus it is possible to avoid a decrease in the pixel aperture ratio caused by shielding the active layer from light by changing the size and shape of the gate.

The step S102 may specifically comprise the following steps as shown in FIG. 5.

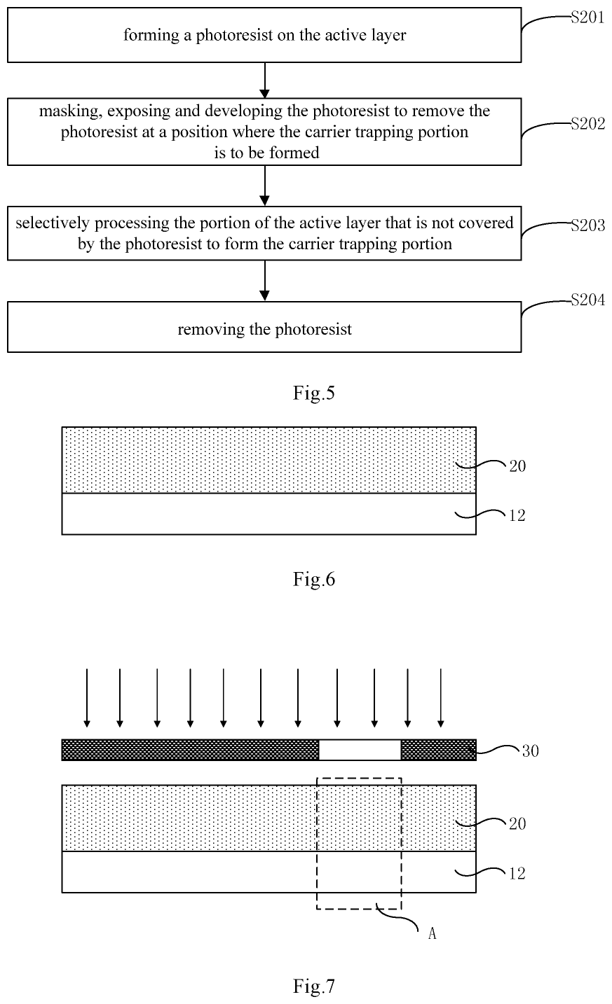

In step S201, as shown in FIG. 6, a photoresist 20 is formed on the active layer 12.

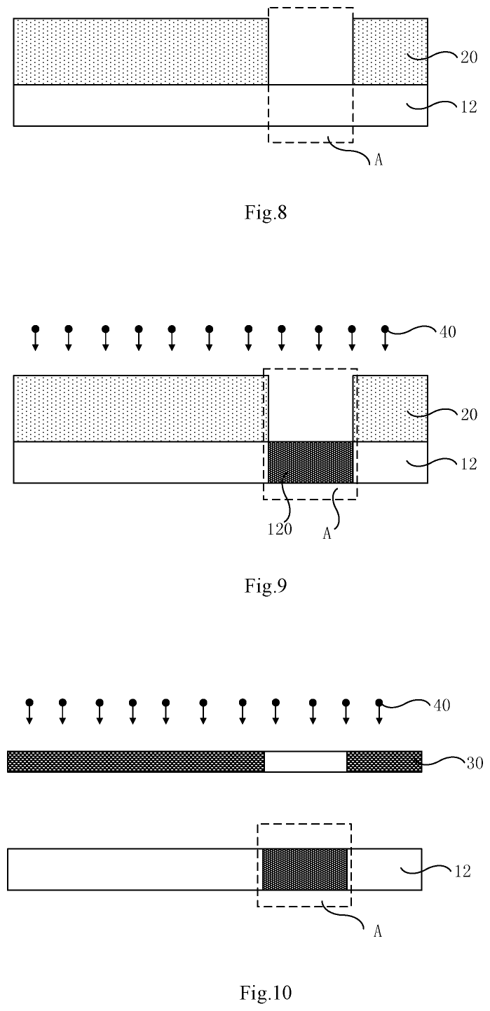

In step S202, as shown in FIG. 7, the photoresist 20 is masked and exposed. Then, as shown in FIG. 8, the photoresist 20 corresponding to a position A where a carrier trapping portion 120 is to be formed is removed by a development process.

The type of the photoresist 20 is not limited in the present disclosure, which may be a positive photoresist or a negative photoresist. Specifically, as shown in FIG. 7 and FIG. 8, the photoresist 20 is illustrated based on the example of a positive photoresist. The photoresist 20 is melted by irradiation of light transmitting transmission regions of a mask 30, and the portion not irradiated by light is not easily melted. The negative photoresist is the contrary case. Details are not described here again.

In step S203, as shown in FIG. 9, the portion of the active layer 12 that is not covered by the photoresist 20 is selectively processed (for example, ion bombardment or ion doping is performed by means of ions 40) to form the carrier trapping portion 120.

In step S204, the photoresist 20 is removed.

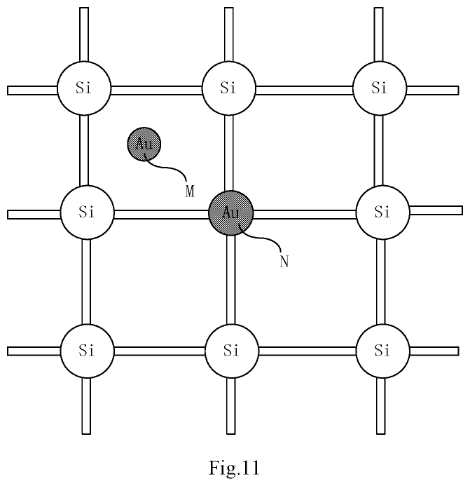

The above process of selectively processing a portion of the active layer 12 comprises performing a patterning process on the photoresist 20 to form a photoresist pattern, and selectively processing a portion of the active layer 12 using the photoresist pattern as a mask. Alternatively, as shown in FIG. 10, a mask 30 may be disposed directly above the active layer 12 such that ions 40 can pass through the transmission regions of the mask 30 under the effect of the mask 30, so as to selectively process the semiconductor active layer 12 at the position A where a carrier trapping portion 120 is to be formed. However, since the ions 40 would cause some damage to the mask 30 in such a process, a portion of the active layer 12 is generally selectively processed by using the photoresist pattern as a mask.

The selectively processing a portion of the active layer to form a carrier trapping portion in the present disclosure may comprise an ion bombardment process or an ion doping process. Specifically, the active layer may be bombarded or doped with ions provided by an ion source. Alternatively, ions provided by an ion source may be accelerated in a high-frequency, high-voltage electric field such that larger particles collide with molecules to ionize the molecules to produce particles such as free electrons, ions, free radicals and so on to form plasmas. In this case, the selectively processing a portion of the active layer to form a carrier trapping portion may refer to bombarding or doping the active layer 12 using ions in the above plasmas.

The ion bombardment process and the ion doping process are described below in detail, respectively.

The carrier trapping portion 120 comprises photo-generated majority carrier traps, i.e. impurities or deficiencies capable of trapping the photo-generated majority carriers in the active layer 12. Specifically, if the active layer 12 comprises an n-type semiconductor material, the carrier trapping portion 120 comprises photo-generated electron traps; if the active layer 12 comprises a p-type semiconductor material, the carrier trapping portion 120 comprises photo-generated hole traps.

On such basis, atoms of an element different from the semiconductor material that constitutes the active layer 12 are doped as impurity atoms into the semiconductor material by an ion doping process to trap the photo-generated majority carriers, thereby forming the above photo-generated majority carrier traps.

Specifically, the ion doping process may be employed in the example in which the traps the semiconductor material constituting the carrier trapping portion 120 has are electron traps. As shown in FIG. 11, doping is performed using gold (Au) ions or copper (Cu) ions. After the above doping process, impurity atoms such as Au may be located at interstitial sites of lattice atoms to form interstitial impurities M. Alternatively, the above impurity atoms may replace the lattice atoms to locate at lattice sites so as to form substitutional impurities N. In this way, the interstitial impurities M and the substitutional impurities N can attract conductive electrons to become negative ions, thereby forming photo-generated electron traps.

In particular, doping of gold (Au) ions is advantageous in forming the electron traps, as it is possible to avoid pollution in the channel caused by the migration of doped copper (Cu) ions to the TFT channel due to the too small size of copper (Cu) ions.

Similarly, when the interstitial impurities M and the substitutional impurities N formed by the doping process can attract valence band holes to become positive ions, photo-generated hole traps can be formed. The energy level of the impurities that constitute the photo-generated hole traps is higher than that of the impurities that constitute the photo-generated electron traps.

During the process of forming the carrier trapping portion by an ion bombardment process, ions of 500 eV to 5 keV may be used to bombard a portion of the active layer 12 for 50 s to 200 s. In this way, an effective bombardment effect can be achieved while ensuring that the active layer 12 is not damaged, so as to form a carrier trapping portion capable of trapping photo-generated majority carriers.

Ions used for bombardment may comprise inert elements such as argon (Ar), neon (Ne), helium (He) and the like. In this way, during the bombardment with ions constituted by the above inert elements, the ions would not change the composition of the active layer, but break the covalent bonds between, for example, silicon (Si) atoms constituting the active layer 12, thereby forming deficiencies that can trap photo-generated majority carriers.

The above embodiments are only specific embodiments of the present disclosure, while the protection scope of the present disclosure is not so limited. Variations or substitutions that can be easily conceived by any skilled person familiar with this technical field within the technical scope revealed by the present disclosure shall be encompassed within the protection scope of the present disclosure. Thus, the protection scope of the present disclosure shall be determined by the protection scope of the attached claims.

1. A thin film transistor comprising: an active layer, a source and a drain above the active layer, wherein
the active layer comprises a carrier trapping portion configured to trap photo-generated majority carriers.

2. The thin film transistor according to claim 1, wherein the carrier trapping portion is between orthographic projections of the source and the drain on the active layer.

3. The thin film transistor according to claim 1, wherein the carrier trapping portion is at a side of the active layer closer to the drain than the source.

4. The thin film transistor according to claim 1 or 2, further comprising a gate, wherein
the carrier trapping portion comprises a first sub-trapping portion and a second sub-trapping portion,
the first sub-trapping portion is between orthographic projections of the gate and the drain on the active layer, and
the second sub-trapping portion is between orthographic projections of the gate and the source on the active layer.

5. The thin film transistor according to claim 4, wherein the thin film transistor is a top gate type thin film transistor.

6. The thin film transistor according to claim 4, wherein each of the first sub-trapping portion and the second sub-trapping portion has a size of about 0.3 μm to 2 μm in a length direction of a channel of the thin film transistor.

7. A manufacturing method of a thin film transistor, comprising:
forming an active layer;
selectively processing a portion of the active layer to form a carrier trapping portion, wherein the carrier trapping portion is configured to trap photo-generated majority carriers;
forming a source and a drain.

8. The manufacturing method of a thin film transistor according to claim 7, wherein the selectively processing a portion of the active layer to form a carrier trapping portion comprises performing a selective ion bombardment process on the portion of the active layer.

9. The manufacturing method of a thin film transistor according to claim 7, wherein the selectively processing a portion of the active layer to form a carrier trapping portion comprises performing a selective ion doping process on the portion of the active layer.

10. The manufacturing method of a thin film transistor according to claim 9, wherein in the case where the carrier trapping portion is configured to trap photo-generated electrons, the selective ion doping process comprises performing selective doping on the portion of the active layer using ions selected from gold ions and copper ions.

11. The manufacturing method of a thin film transistor according to claim 8, wherein the ion bombardment process comprises performing selective bombardment on the portion of the active layer using ions of about 500 eV to 5 keV for about 50 s to 200 s.

12. The manufacturing method of a thin film transistor according to claim 11, wherein the ions comprise inert elements.

13. An array substrate comprising a substrate, and the thin film transistor according to claim 1 on the substrate.

14. A display device comprising the array substrate according to claim 13.

15. The thin film transistor according to claim 1, wherein the active layer is an n-type active layer, and the carrier trapping portion is configured to trap photo-generated electrons.

16. The thin film transistor according to claim 1, wherein the active layer is a p-type active layer, and the carrier trapping portion is configured to trap photo-generated holes.

17. The array substrate according to claim 13, wherein the carrier trapping portion is between orthographic projections of the source and the drain on the active layer.

18. The array substrate according to claim 13, wherein the carrier trapping portion is at a side of the active layer closer to the drain than the source.

19. The array substrate according to claim 13, further comprising a gate, wherein
the carrier trapping portion comprises a first sub-trapping portion and a second sub-trapping portion,
the first sub-trapping portion is between orthographic projections of the gate and the drain on the active layer, and
the second sub-trapping portion is between orthographic projections of the gate and the source on the active layer.

20. The array substrate according to claim 19, wherein the thin film transistor is a top gate type thin film transistor.
